(19) United States
(12) Patent Application Publication
(10) Pub. No.: US 2025/0164667 A1
(43) Pub. Date: May 22, 2025

(54) OPTICAL LENS AND METHOD FOR PREPARING THE SAME

(71) Applicant: AAC OPTICS (CHANGZHOU) CO., LTD., Changzhou City (CN)

(72) Inventors: Shuxian Wang, Changzhou (CN); Jia Wang, Changzhou (CN)

(21) Appl. No.: 18/741,809

(22) Filed: Jun. 13, 2024

(30) Foreign Application Priority Data
Nov. 22, 2023 (CN) 202311570255.7

(51) Int. Cl. G02B 1/11

(52) U.S. Cl. CPC G02B 1/11

(57) ABSTRACT

An optical lens includes: a substrate; and a film layer arranged on one side or two opposite sides of the substrate. The film layer includes a metal organic skeleton plating film layer attached to the substrate, and the metal organic skeleton plating film layer has a refractive index ranging from 1.0 to 1.37. The optical lens has a relatively low reflectivity and a relatively high transmittance in a wide wavelength range. A super-porous structure of the optical lens is relatively low in roughness and small in imaging scattering. The super-porous material of the optical lens is formed by coordination chemical bonds, its pores are distributed uniformly, reflectivity and transmittance are stable. The metal organic skeleton plating film layer of the optical lens is not easy to be damaged in the manufacturing process, and the yield is high. Meanwhile, the preparation process is simple, achieving high yield and low cost.

### TECHNICAL FIELD

The present disclosure relates to the technical field of optics, in particular to an optical lens and a method for preparing the optical lens.

### BACKGROUND

With the continuous development of camera optical lenses, the requirements for optical lenses are getting higher and higher, i.e., characteristics of high transmittance, low reflectivity and low scattering in a wide waveband range are required to obtain lens with high imaging quality.

In the related art, a main solution is to plate the optical lens with one of magnesium fluoride plating film, grassy aluminum oxide plating film and silicon dioxide air ball plating film to satisfy the above requirements. However, the refractive index of magnesium fluoride is not low enough, so that it cannot meet the relatively low reflectivity in a relatively wide wavelength range. The optical lens with magnesium fluoride plating film has relatively high stress, and is generally poor in reliability, the structure generally cooperates with 6-10 layers of dielectric film to reduce reflectivity, the total layer number of plating film is large, the plating efficiency is low, and the cost is relatively high. The roughness of the grassy aluminum oxide layer is large, so that the grassy aluminum oxide layer has relatively strong scattering for incident light, affecting the imaging quality. The porous grassy aluminum oxide has a relatively strong adsorption effect, it is easy to adsorb organic matters to result in reflectivity change. The film layer is fragile, which is easy to cause a low yield in the manufacturing process. The air balls of the silicon dioxide air ball plating film are liable to be distributed unevenly, resulting in large reflectivity fluctuation. The manufacturing process of the silicon dioxide air ball plating layer is difficult to control, so that the cost is high, and it is not suitable for mass production.

Therefore, it is necessary to provide a new optical lens and a method for preparing the optical lens to solve the above technical problems.

### SUMMARY

An object of the present disclosure is to provide an optical lens and a method for preparing the optical lens, which aims to solve the problems of complex preparation process, low yield, high cost, high reflectivity and low transmittance in a wide wavelength range in the related art.

In a first aspect, the present disclosure provides an optical lens. The optical lens includes: a substrate; and a film layer arranged on one side or two opposite sides of the substrate. The film layer includes a metal organic skeleton plating film layer attached to the substrate, and the metal organic skeleton plating film layer has a refractive index ranging from 1.0 to 1.37.

As an improvement, the film layer further includes a dielectric film sandwiched between the substrate and the metal organic skeleton plating film layer, and the dielectric film includes a high refractive index material layer and a low refractive index material layer;
wherein the high refractive index material layer has the refractive index ranging from 2.0 to 3.0; and the low refractive index material layer has the refractive index ranging from 1.2 to 1.8.

As an improvement, the dielectric film is formed by alternately stacking the high refractive index material layer and the low refractive index material layer for N times, where N is a natural number.

As an improvement, the high refractive index material layer is made of one of titanium oxide, zirconium oxide and hafnium oxide.

As an improvement, the low refractive index material layer is made of one of silicon oxide, aluminum oxide and magnesium fluoride.

As an improvement, the substrate is made of one of an environment-friendly plastic raw material, epoxy resin and polycarbonate.

As an improvement, a thickness of the metal organic skeleton plating film layer ranges from 30 nm to 300 nm.

As an improvement, the metal organic skeleton plating film layer includes a super-porous material formed by metal and organic compounds by coordination chemical bond, and the super-porous material has a pore diameter smaller than 3 nm.

As an improvement, the super-porous material includes one of IRMOFs, ZIFs, CLPs, MILs, PCNs, and UiO.

As an improvement, the IRMOFs are formed by [Zn₄O]⁶⁺ and a plurality of aromatic carboxylic acid ligands.

As an improvement, the ZIFs are formed by Zn²⁺ or Co²⁺ and an imidazole ester. As an improvement, the CLPs are formed by a hexacoordination metal element and

a nitrogen heterocyclic ligand.

As an improvement, the MILs are formed by a transition metal element and a dicarboxylate ligand.

As an improvement, the PCNs are composed of a material including a plurality of cubic octahedral nanoholes.

As an improvement, the UiO is composed of [Zr₆O₄(OH)₄] and terephthalate.

As an improvement, the optical lens has a reflectivity of ≤1% at a wavelength ranging from 380 nm to 720 nm, a transmittance of ≥90%, a reflectivity of ≤0.5% at a wavelength ranging from 420 nm to 680 nm, and a transmittance of ≥95%.

In a second aspect, the present disclosure provides a method for preparing an optical lens as described in the first aspect. The method includes:
forming a substrate into a lens structure;
plating a dielectric film on one side or two opposite sides of the substrate formed;
forming a metal organic skeleton plating film layer on a side of the dielectric film away from the substrate;
wherein the dielectric film is formed by one of physical vapor deposition, magnetron sputtering and atomic layer deposition; and
wherein the metal organic skeleton plating film layer is formed by one of hydrothermal/solvothermal method, electrochemical method, mechanochemical synthesis method, solid phase-gas phase method and chemical vapor deposition method.

### BRIEF DESCRIPTION OF DRAWINGS

Many aspects of the exemplary embodiment can be better understood with reference to following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a structural schematic diagram of an optical lens according to an embodiment of the present disclosure;

FIG. 2 is a schematic diagram of reflectivity of an optical lens according to an embodiment of the present disclosure;

FIG. 3 is a schematic diagram of transmittance of an optical lens according to an embodiment of the present disclosure; and

FIG. 4 is a flowchart of a method for preparing an optical lens according to an embodiment of the present disclosure.

### DESCRIPTION OF EMBODIMENTS

The technical solutions in embodiments of the present disclosure will be described clearly and completely below in connection with the drawings in the embodiments of the present disclosure, and it will be apparent that the embodiments described here are merely a part, not all of the embodiments of the present disclosure. All other embodiments obtained by those of ordinary skill in the art based on the embodiments of the present disclosure should fall within the protection scope of the present disclosure.

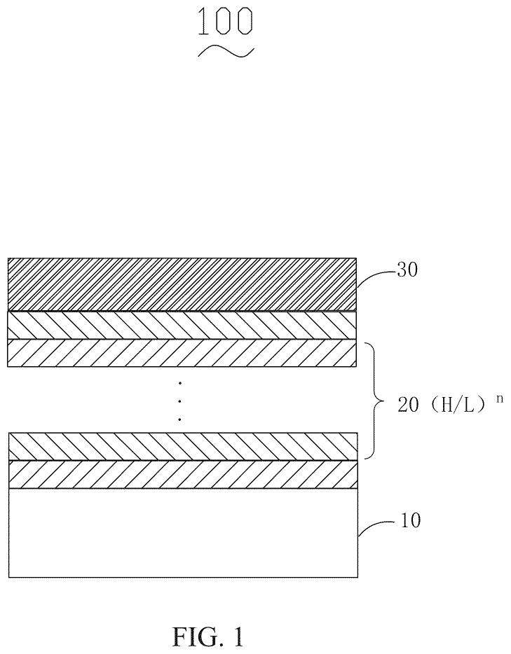

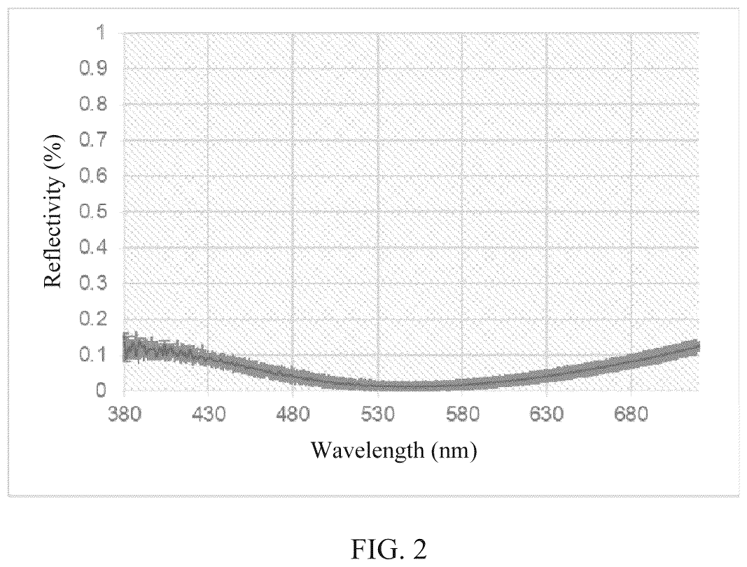

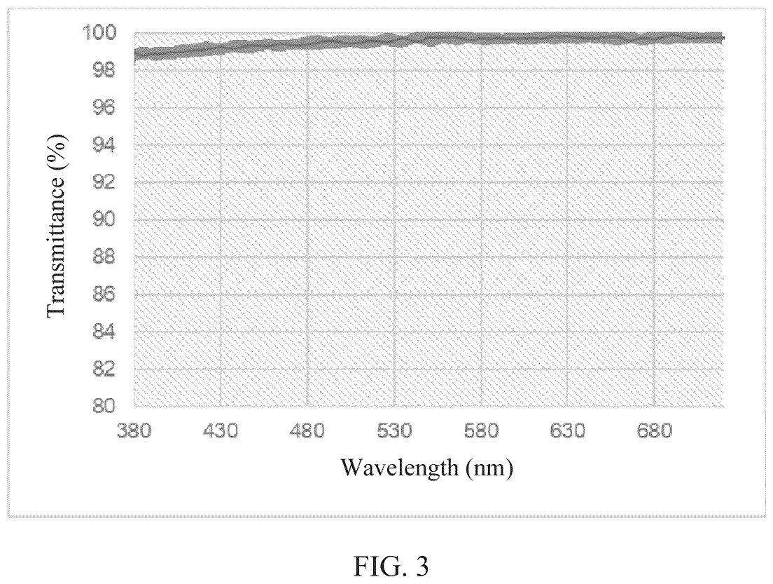

Referring to FIG. 1 to FIG. 3, the present disclosure provides an optical lens 100. The optical lens 100 includes: a substrate 10 and a film layer arranged on one side or two opposite sides of the substrate 10.

The film layer includes a metal organic skeleton plating film layer 30 attached to the substrate 10. The metal organic skeleton plating film layer has a refractive index ranging from 1.0 to 1.37.

In an embodiment, the film layer further includes a dielectric film sandwiched between the substrate 10 and the metal organic skeleton plating film layer 30. The dielectric film 20 includes a high refractive index material layer H and a low refractive index material layer L. The high refractive index material layer has a refractive index ranging from 2.0 to 3.0. The low refractive index material layer has a refractive index ranging from 1.2 to 1.8.

In an embodiment, the dielectric film 20 is formed by alternately stacking the high refractive index material layer H and the low refractive index material layer L for N times, and the high refractive index material layer H has a refractive index ranging from 2.0 to 3.0. The low refractive index material layer L has a refractive index ranging from 1.2 to 1.8. N is a natural number.

In an embodiment, the high refractive index material layer H includes any one of titanium oxide, zirconium oxide and hafnium oxide.

In an embodiment, the low refractive index material layer L includes any one of silicon oxide, aluminum oxide and magnesium fluoride.

In an embodiment, the substrate 10 is an optical material, and may be made of any one of cyclic olefin copolymer APEL series (MITSUI CHEMICALS, INC), cyclic olefin copolymer K26R, K22R, E48R, and the like (Japan ZEON Corporation), a polyester Iupizeta EP series (MITSUBISHI GAS CHEMICAL), polycarbonate such as an SP series (TEIJIN LIMITED), and a glass material.

In an embodiment, the metal organic skeleton plating film layer 30 has a thickness ranging from 30 nm to 300 nm.

In an embodiment, the metal organic skeleton plating film layer 30 is made of a super-porous material formed by metal and organic compounds by coordination chemical bonds.

In an embodiment, a pore diameter of the super-porous material is <3 nm.

In an embodiment, the super-porous material includes any one of IRMOFs, ZIFs, CLPs, MILs, PCNs, and UiO.

In an embodiment, the IRMOFs are formed by [Zn₄O]⁶⁺ and a plurality of aromatic carboxylic acid ligands.

In an embodiment, the ZIFs are formed by Zn²⁺ or Co²⁺ and imidazole esters. For example, the ZIFs can be zinc imidazole, cobalt imidazole, zinc 2-methylimidazole, cobalt 2-methylimidazole, zinc 2-ethyl imidazole, cobalt 2-ethyl imidazole, zinc benzimidazole, and cobalt benzimidazole.

In an embodiment, the CLPs are formed by a hexacoordination metal element and a nitrogen heterocyclic ligand.

In an embodiment, the MILs are formed by a transition metal element and a dicarboxylate ligand (e.g., succinic acid, glutaric acid, or the like).

In an embodiment, PCNs are composed of a material including a plurality of cubic octahedral nanoholes.

In an embodiment, the UiO is composed of [Zr₆O₄(OH)₄] and terephthalate.

In an embodiment, the optical lens 100 has a reflectivity≤1% at a wavelength of 380 nm-720 nm and a reflectivity≤0.5% at a wavelength of 420 nm-680 nm.

In an embodiment, the optical lens 100 has a transmittance≥90% at a wavelength of 380 nm-720 nm and a transmittance≥95% at a wavelength ranging from 420 nm to 680 nm.

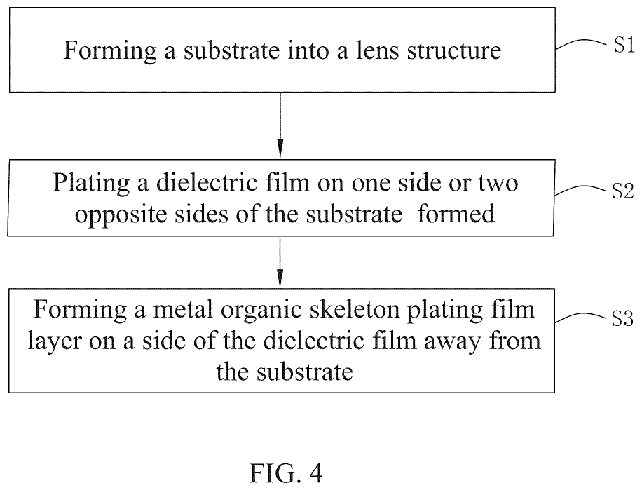

In a second aspect, referring to FIG. 4, the present disclosure provides a method for preparing the optical lens 100 according to any one of the above embodiments. The method includes following steps.
S1, the substrate 10 is formed into a lens structure;
S2, a dielectric film 20 is formed on one side or two opposite sides of the substrate 10 formed;
S3, the metal organic skeleton plating film layer 30 is formed on a side of the dielectric film 20 away from the substrate 10.

The dielectric film 20 is formed by one of physical vapor deposition, magnetron sputtering and atomic layer deposition.

The metal organic skeleton plating film layer 30 is formed by one of hydrothermal/solvothermal method, electrochemical method, mechanochemical synthesis method, solid phase-gas phase method and chemical vapor deposition method.

Compared with the related art, the optical lens provided by the present disclosure has a relatively low reflectivity and a relatively high transmittance in a wide wavelength range. A super-porous structure of the optical lens is relatively low in roughness and small in imaging scattering. The super-porous material of the optical lens is formed by coordination chemical bonds, its pores are distributed uniformly, the reflectivity and transmittance are stable. The metal organic skeleton plating film layer of the optical lens is not easy to be damaged in the manufacturing process, and the yield is high. Meanwhile, the preparation process of the optical lens provided by the present disclosure is simple, achieving high yield and low cost.

The above description is only exemplary embodiments of the present disclosure. It should be noted that those skilled in the art can further make improvements without departing from the concept of the present disclosure, but these improvements fall within the protection scope of the present disclosure.

What is claimed is:

1. An optical lens, comprising: a substrate; and
a film layer arranged on one side or two opposite sides of the substrate;
wherein the film layer comprises a metal organic skeleton plating film layer attached to the substrate, and the metal organic skeleton plating film layer has a refractive index ranging from 1.0 to 1.37.

2. The optical lens as described in claim 1, wherein the film layer further comprises a dielectric film sandwiched between the substrate and the metal organic skeleton plating film layer, and the dielectric film comprises a high refractive index material layer and a low refractive index material layer;
wherein the high refractive index material layer has the refractive index ranging from 2.0 to 3.0; and the low refractive index material layer has the refractive index ranging from 1.2 to 1.8.

3. The optical lens as described in claim 2, wherein the dielectric film is formed by alternately stacking the high refractive index material layer and the low refractive index material layer for N times, where N is a natural number.

4. The optical lens as described in claim 3, wherein the high refractive index material layer is made of one of titanium oxide, zirconium oxide and hafnium oxide.

5. The optical lens as described in claim 3, wherein the low refractive index material layer is made of one of silicon oxide, aluminum oxide and magnesium fluoride.

6. The optical lens as described in claim 2, wherein the substrate is made of one of an environment-friendly plastic raw material, epoxy resin and polycarbonate.

7. The optical lens as described in claim 2, wherein a thickness of the metal organic skeleton plating film layer ranges from 30 nm to 300 nm.

8. The optical lens as described in claim 2, wherein the metal organic skeleton plating film layer comprises a super-porous material formed by metal and organic compounds by coordination chemical bond, and the super-porous material has a pore diameter smaller than 3 nm.

9. The optical lens as described in claim 8, wherein the super-porous material comprises one of IRMOFs, ZIFs, CLPs, MILs, PCNs, and UiO.

10. The optical lens as described in claim 9, wherein the IRMOFs are formed by [Zn₄O]⁶⁺ and a plurality of aromatic carboxylic acid ligands.

11. The optical lens as described in claim 9, wherein the ZIFs are formed by Zn²⁺ or Co²⁺ and an imidazole ester.

12. The optical lens as described in claim 9, wherein the CLPs are formed by a hexacoordination metal element and a nitrogen heterocyclic ligand.

13. The optical lens as described in claim 9, wherein the MILs are formed by a transition metal element and a dicarboxylate ligand.

14. The optical lens as described in claim 9, wherein the PCNs are composed of a material comprising a plurality of cubic octahedral nanoholes.

15. The optical lens as described in claim 9, wherein the UiO is composed of [Zr₆O₄(OH)₄] and terephthalate.

16. The optical lens as described in claim 2, wherein the optical lens has a reflectivity of ≤1% at a wavelength ranging from 380 nm to 720 nm, a transmittance of ≥90%, a reflectivity of ≤0.5% at a wavelength ranging from 420 nm to 680 nm, and a transmittance of ≥95%.

17. A method for preparing an optical lens as described in claim 2, comprising:
forming a substrate into a lens structure;
plating a dielectric film on one side or two opposite sides of the substrate formed;
forming a metal organic skeleton plating film layer on a side of the dielectric film away from the substrate;
wherein the dielectric film is formed by one of physical vapor deposition, magnetron sputtering and atomic layer deposition; and
wherein the metal organic skeleton plating film layer is formed by one of hydrothermal/solvothermal method, electrochemical method, mechanochemical synthesis method, solid phase-gas phase method and chemical vapor deposition method.
